(19) United States
(12) Patent Application Publication
(10) Pub. No.: US 2025/0151493 A1
(43) Pub. Date: May 8, 2025

(54) SELECTIVE RELEASE OF MICRODEVICES

(71) Applicant: VueReal Inc., Waterloo (CA)

(72) Inventor: Gholamreza CHAJI, Waterloo (CA)

(73) Assignee: VueReal Inc., Waterloo, ON (CA)

(21) Appl. No.: 18/682,578

(22) PCT Filed: Aug. 9, 2022
(86) PCT No.: PCT/CA2022/051211

§ 371 Date: Feb. 9, 2024

Related U.S. Application Data
(60) Provisional application No. 63/230,875, filed on Aug. 9, 2021.

(51) Int. Cl. H10H 29/02

(52) U.S. Cl. CPC H10H 29/02

(57) ABSTRACT

The invention disclose method to selectively transfer microdevices from a cartridge substrate to a system substrate by bringing a cartridge substrate closer to the system substrate, wherein the release layer for the first selected microdevice from the cartridge substrate is modified or removed prior to the transfer such that the selected microdevice is held to the cartridge substrate with a lower force than the bonding force of the selected microdevice to the pad.

### FIELD OF THE INVENTION

The invention relates to development of microdevices on a substrate that can be released and transferred to a system substrate.

### BRIEF SUMMARY

The invention relates to a method to selectively transfer microdevices from a cartridge substrate to a system substrate, the method comprising, bringing a cartridge substrate closer to the system substrate, bringing a selected microdevice in contact with pads in the system substrate, bonding the selected microdevice to the pads in the system substrate, and where the release layer for the first selected microdevice from the cartridge substrate is modified or removed prior to the transfer such that the selected microdevice is held to the cartridge substrate with a lower force than the bonding force of the selected microdevice to the pad.

### BRIEF DESCRIPTION OF THE DRAWINGS

The foregoing and other advantages of the disclosure will become apparent upon reading the following detailed description and upon reference to the drawings.

FIG. 1 shows transfer setup 100 enabling microdevices in a donor/cartridge substrate to be transferred to a system substrate.

FIG. 2(a), shows the selected set of microdevice(s) are aligned with the selected system substrate bonding pads.

FIG. 2(b), shows a release layer is removed and the first selected microdevice is transferred to the system substrate.

FIG. 2(c), shows a second set of selected microdevices are aligned with the second bonding pads on the system substrate.

FIG. 2(d), shows the second selected microdevice set is transferred into the system substrate.

FIG. 2(e), shows a third set of selected microdevices are aligned with the third bonding pads on the system substrate.

FIG. 2(f), shows the third selected microdevice set 104-3 is transferred into the system substrate.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

In this description, the term “device” and “microdevice” are used interchangeably. However, it is clear to one skilled in the art that the embodiments described here are independent of the device size.

Microdevices can be microLED, OLED, microsensors, MEMs, and any other type of devices.

In one case, the microdevice has a functional body and contacts. The contacts can be electrical, optical or mechanical contacts.

In the case of optoelectronic microdevices, the device can have functional layers and charge carrying layers. Where charge carrying layers (doped layers, ohmics and contacts) transfer the charges (electron of hole) between the functional layers and contacts outside the device. The functional layers can generate electromagnetic signals (e.g., lights) or absorb electromagnetic signals.

System substrates can have pixels and pixel circuits that each pixel control at least one microdevice. Pixel circuits can be made of electrodes, transistors or other components. The transistors can be fabricated with a thin film process, CMOS, or organic materials.

The invention described and its related embodiments show a method to selectively transfer microdevices from a donor/cartridge substrate to a system substrate.

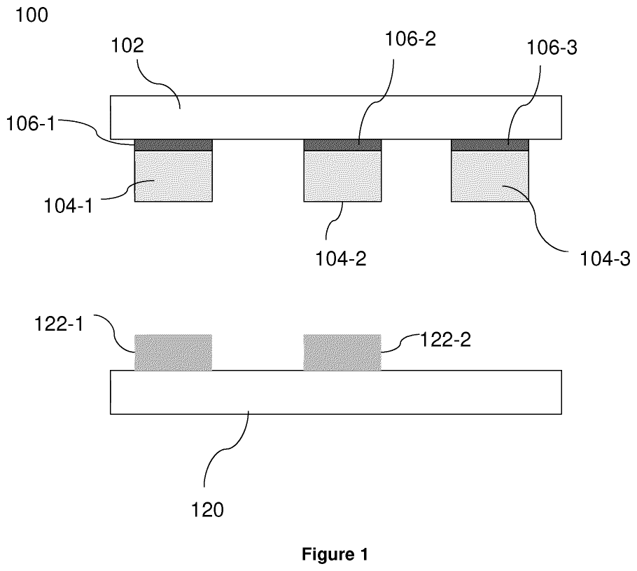

FIG. 1 shows transfer setup 100 enabling microdevices 104-1 in a donor/cartridge substrate 102 to be transferred to a system substrate 120. Here, the selected microdevices 104-1 are transferred to a transfer area or pad 122-1 in a system substrate 120. The cartridge substrate 102 and system substrate 120 are brought close together so the microdevice 104-1 contacts the area or pads 122-1 in the system substrate. The microdevice 104-1 or its pads get bonded to the pad 122-1 and hold the microdevice 104-1. The microdevice is released from the donor substrate 102. To facilitate the release process, a release layer 106-1 has been removed or changed so the microdevice 104-1 is held to the cartridge substrate 102 with lower force than the bonding force of microdevice 104-1 to the pad 122-1. The pad 122-1 (or 122-2) can have a multi part, a bonding part, a conductive part. The bonding part can be separate from the conductive part. The conductive part can be deposited after the transfer, or it is formed prior to the transfer. There can be other microdevices 104-2 in the donor substrate that can interfere with the other bonding pad 122-2. Therefore, to avoid microdevice transfer to the system substrate, the release layer 106-2 associated with an unselected microdevice 104-2 is not changed or removed.

There can be other microdevices 104-3 in the donor/cartridge substrate 102 that do not interfere with another pad on the system substrate. The release layer 106-3 for these devices 104-3 can be changed or not.

The selective removal or change of the release layer for microdevices that are being transferred to the system substrate and do not interfere with the unwanted area can be done through selective chemical process, etching, thermal, or laser process.

For selective chemical processes, a photoresist can be patterned on the donor substrate and enable access to the selective microdevices 104-1. As a result, the chemical can only change or remove the release layer 106-1 associated with the selected microdevices. After the selected microdevices are transferred (it can be in one transfer cycle or multiple transfer cycles), another photoresist can be patterned and enable access to the newly selected microdevices.

In another related embodiment, different release layers can be used so that each release layer is modified or removed by a selected chemical. As a result, the first chemical removes the release layer 106-1 related to the selected microdevice 104-1. After transferring the first selected microdevices to the system substrate, a second chemical is used that removes or modifies the release layer associated with the second set of microdevices.

In another related embodiment, the different release layer in a donor substrate can have different modification or removal mechanisms such as one set can have a chemical release layer, one set laser and so on.

In another related embodiment, the bonding part of the pads can be formed only for the first selected microdevices. After the transfer of the first selected microdevices, the bonding part of the pads for the second selected microdevices are formed on the system substrate. This process enables further selectivity.

In another related embodiment, the bonding part of the microdevices related to the repair process are formed after the testing and identifying the defective microdevices (or pixels) in the system substrate.

In related embodiments microdevices can be coupled to the backplane or another housing layer through a membrane or anchor layer.

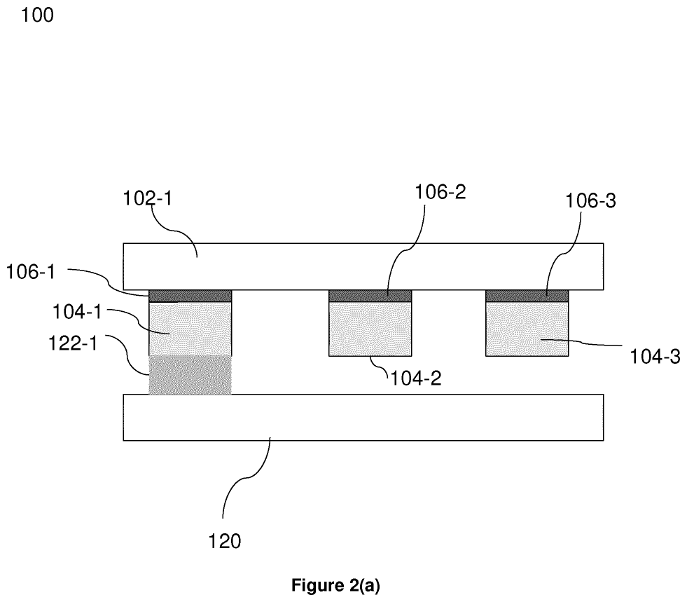

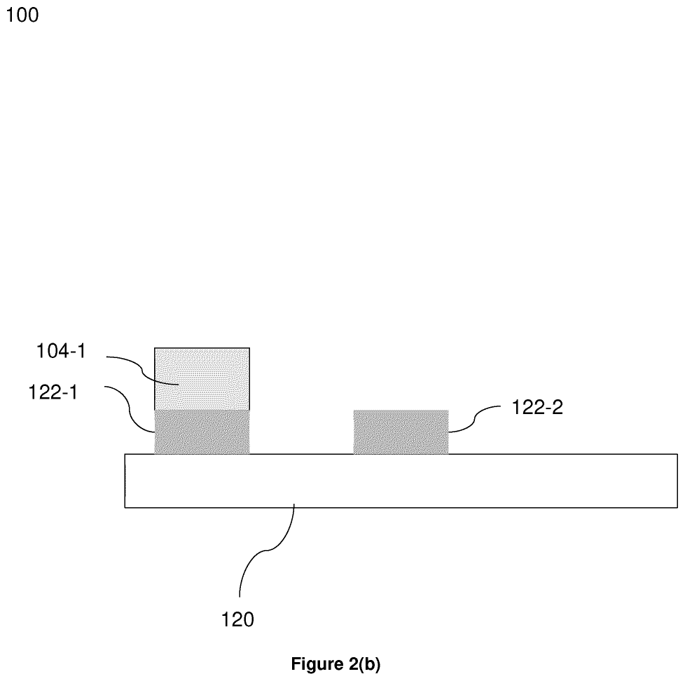

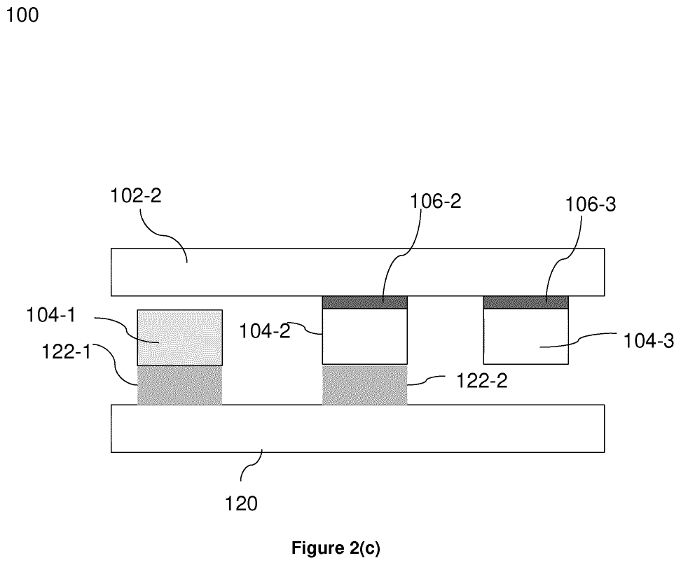

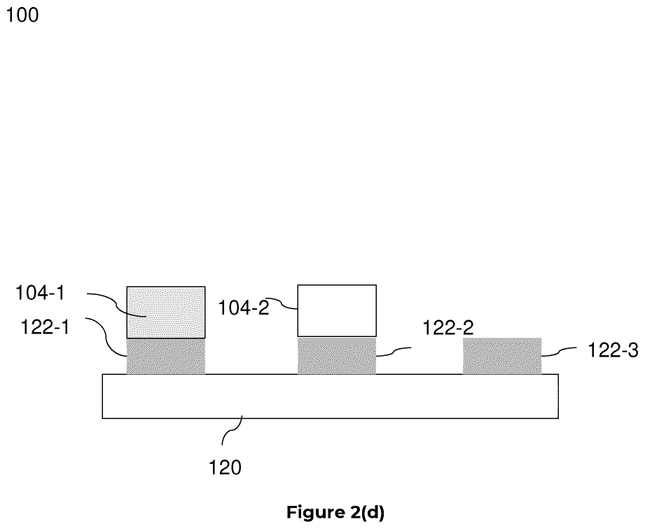

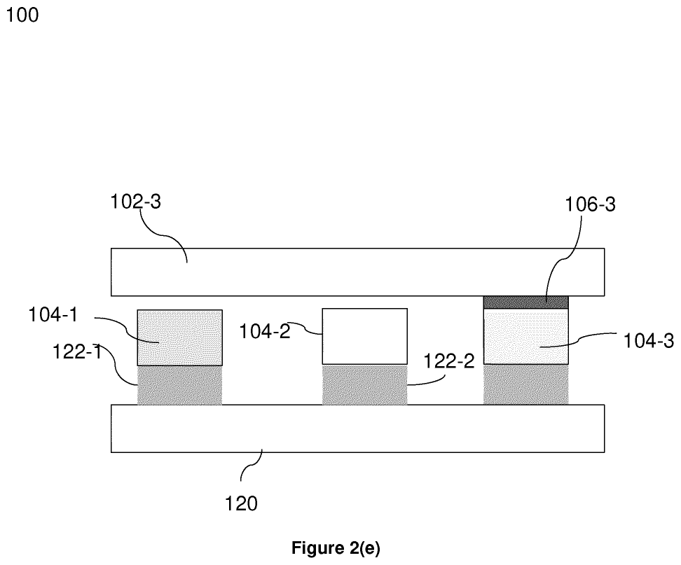

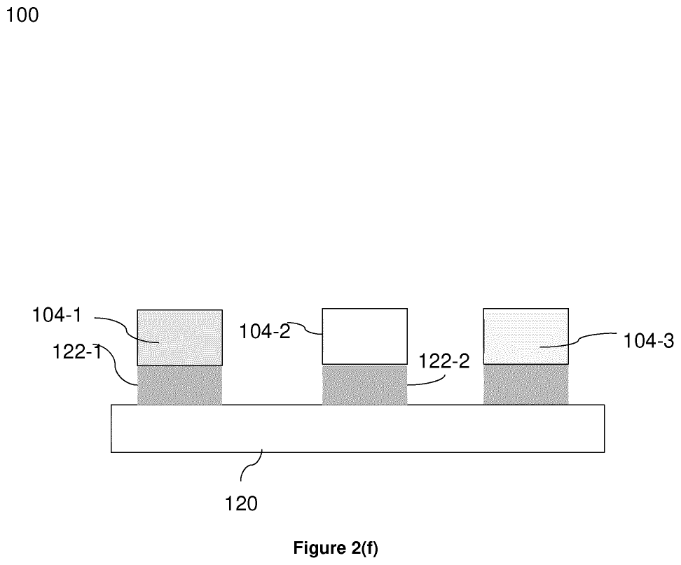

FIG. 2 shows another related embodiment where different devices are transferred into the system substrate. For the first set of selected microdevices 104-1, a first bonding pad 122-1 is deposited on the substrate 120. For other microdevices different from the first microdevices, there can be no bonding pads on the substrate (or if the bonding force with the microdevice will be less than the release layers 106-2 and 106-3 bonding of microdevices to the cartridge 102-1). There can be conductive parts of the pads on the system substrate for all microdevices.

As demonstrated in FIG. 2(a), the selected set of microdevice(s) 104 are aligned with the selected system substrate bonding pads 122-1. The microdevice is bonded to the pads 122-1 while the force of its release layer 106-1 is reduced or the release layer is removed and the first selected microdevice 104-1 is transferred to the system substrate 120 (FIG. 2(b)). The unselected microdevices 104-2 and 104-3 are not transferred to the system substrate 120 either as there are no bonding pads or the bonding pad has less force than the release layers 106-2 and 106-3. The process for the first set of selected microdevices can be repeated till the desired or target area of the backplane is fully or partially populated. The release layer associated with the first microdevice can be either removed or changed prior to the transfer.

A second bonding pad set is formed onto the system substrate 120. The second set bonding pad exists on the system substrate and gets activated. The activation can be by removing a top layer, thermal, plasma, or other factors.

As demonstrated in FIG. 2(c), a second set of selected microdevices are aligned with the second bonding pads 122-2 on the system substrate 120. The release layer for the second set of microdevices 106-2 is either removed or modified to have less bonding force. The area in the second donor substrate 102-2 that interferes with the first transferred microdevice 104-1 has no microdevice. The second microdevice donor substrate 102-2 can be used to transfer the second microdevice associated with the first microdevice in the current system substrate 120 in another system substrate or part of the system substrate or temporary substrate that has no first microdevice.

FIG. 2d shows the second selected microdevice set 104-2 is transferred into the system substrate. The process for the second set of selected microdevices can be repeated till the desired area of the backplane is fully or partially populated. The release layer associated with the second microdevice can be either removed or changed prior to the transfer.

As shown in FIG. 2(d) a third bonding pad 122-3 can be formed on the substrate 120. The pads can be formed after the second microdevice 104-2 is transferred or prior to that. The pad can be activated by removing a top layer, plasma process, wetting, thermal or laser.

As demonstrated in FIG. 2(e), a third set of selected microdevices are aligned with the third bonding pads 122-3 on the system substrate 120. The release layer for the third set of microdevices 106-3 is either removed or modified to have less bonding force. The area in the third donor substrate 102-3 that interferes with the first and second transferred microdevice 104-1 104-2 has no microdevice. The third microdevice donor substrate 102-3 can be used to transfer the third microdevice associated with the first and second microdevices in the current system substrate 120 in another system substrate or part of the system substrate or temporary substrate that has no first microdevice or second microdevice.

FIG. 2(f) shows the third selected microdevice set 104-3 is transferred into the system substrate 120. The process for the third set of selected microdevices can be repeated till the desired area of the backplane is fully or partially populated. The release layer associated with the third microdevice can be either removed or changed prior to the transfer.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

1. A method to selectively transfer microdevices from a cartridge substrate to a system substrate, the method comprising:
bringing a cartridge substrate closer to the system substrate;
bringing a first selected microdevice in contact with pads in the system substrate;
bonding the selected microdevice to the pads in the system substrate; and
wherein a release layer for the first selected microdevice from the cartridge substrate is modified or removed prior to the transfer such that the first selected microdevice is held to the cartridge substrate with a lower force than the bonding force of the selected microdevice to the pad.

2. The method of claim 1, wherein the pad is a multi-part with a conductive part and a bonding part.

3. The method of claim 1, wherein the release of the first selected microdevice is by removing or changing a first release layer through a selective chemical process, an etching, a thermal, or a laser process.

4. The method of claim 1, wherein a second release layer is associated with an unselected microdevice in the cartridge substrate.

5. The method of claim 3, wherein for the selective chemical process, a photoresist is patterned on the cartridge substrate to enable access to the selective microdevice.

6. The method of claim 5, wherein another photoresist is patterned to enable access to the newly selected microdevices after the transfer.

7. The method of claim 2, wherein different release layers are used so that each release layer is modified or removed by a selected chemical such that a first chemical removes the release layer related to the selected microdevice.

8. The method of claim 7, wherein after transferring a first selected set of microdevices to the system substrate, a second chemical is used that removes or modifies a release layer associated with a second set of microdevices.

9. The method of claim 2, wherein a different release layer in a donor substrate has a different modification or removal mechanisms.

10. The method of claim 2, wherein the bonding part of the pads is formed only for the first selected microdevices whereas the bonding part of the pads for second selected microdevices is formed on the system substrate after the transfer of the first selected microdevices.

11. The method claim 2, wherein the bonding part of the microdevices related to a repair process are formed after a testing and identification of defective microdevices in the system substrate.

12. The method of claim 2, wherein unselected microdevices are not transferred to the system substrate as there are no bonding pads or the bonding pad has less force than the corresponding release layers.

13. The method of claim 12, wherein the process for the first set of selected microdevices is repeated till a target area of the system substrate is fully or partially populated.

14. The method of claim 12, wherein a second bonding pad set is formed onto the system substrate and is activated by removing a top layer, thermal, plasma, or other factors.

15. The method claim 14, further comprising:
aligning a second set of microdevices with the second bonding pads; and
modifying or removing a release layer for the second set of microdevices to have less bonding force to the cartridge substrate than a bonding force with the second set of pads.

16. The method of claim 15, wherein an area in the second donor substrate that interferes with the first transferred microdevice has no microdevice.

17. The method of claim 14, wherein the second microdevice donor substrate is used to transfer a second microdevice associated with the first microdevice in the system substrate in another system substrate or part of the system substrate or a temporary substrate that has no first microdevice.

18. The method of claim 14, wherein the second selected microdevice set is transferred into the system substrate and this process for the second set of selected microdevices transfer is repeated till a target area of the system substrate is fully or partially populated and the release layer associated with the second microdevice is either removed or changed prior to the transfer.

19. The method of claim 18, wherein a third bonding pad is formed on the system substrate after the second microdevice is transferred or prior to that and the third bonding pad is activated by removing a top layer, a plasma process, wetting, thermal or laser.

20. The method of claim 19, further comprising:
aligning a third set of selected microdevices are aligned with the third bonding pads on the system substrate; and
removing or modifying a release layer for the third set of microdevices to have less bonding force to the cartridge substrate than the bonding force with the third set of pads and wherein an area in a third donor substrate that interferes with the first and second transferred microdevice has no microdevice.

21. The claim of method 20, wherein the third microdevice donor substrate is used to transfer a third microdevice associated with the first and second microdevices in the system substrate in another system substrate or part of the system substrate or the temporary substrate that has no first microdevice or second microdevice.

22. The method of claim 21, wherein the third selected microdevice set is transferred into the system substrate and this process for the second set of selected microdevices transfer is repeated till a target area of the system substrate is fully or partially populated and the release layer associated with the third microdevice is either removed or changed prior to the transfer.
